(19) United States
(12) Patent Application Publication
(10) Pub. No.: US 2024/0023309 A1
(43) Pub. Date: Jan. 18, 2024

(54) SEMICONDUCTOR ELEMENT MEMORY DEVICE

(71) Applicant: Unisantis Electronics Singapore Pte. Ltd., Singapore (SG)

(72) Inventors: Koji SAKUI, Tokyo (JP); Nozomu HARADA, Tokyo (JP)

(21) Appl. No.: 18/361,478

(22) Filed: Jul. 28, 2023

Related U.S. Application Data
(63) Continuation-in-part of application No. PCT/JP2021/003694, filed on Feb. 2, 2021.

(51) Int. Cl. H10B 12/00; G11C 11/404; G11C 11/4091; G11C 11/4096

(52) U.S. Cl. CPC H10B 12/20; G11C 11/404; G11C 11/4091; G11C 11/4096

(57) ABSTRACT

A semiconductor memory device includes a semiconductor base body (Si pillar) erected or horizontally laid on a substrate; first and second impurity regions located on opposite ends of the semiconductor base body; and gate insulating layer and first and second gate conductor layers located between the impurity regions, surrounding the semiconductor base body. By applying voltages to the impurity regions and gate conductor layers, a current is passed between the impurity regions, thereby causing impact ionization phenomenon in a semiconductor base body to generate electron groups and positive hole groups. A memory write operation is performed to remove the electron groups from the semiconductor base body and hold part of the positive hole groups in the semiconductor base body. A memory erase operation is performed by removing positive hole groups held in the semiconductor base body from the first and/or second impurity region(s). Two semiconductor elements make up one memory cell.

### INCORPORATION BY REFERENCE

The present application is a Continuation-In-Part application of PCT/JP2021/003694, filed Feb. 2, 2021, the entire contents of which are incorporated herein by reference.

### BACKGROUND OF THE INVENTION

### Field of the Invention

The present invention relates to a semiconductor memory device that uses semiconductor elements.

### Description of the Related Art

Recently, there has been demand for greater packaging density and higher performance of memory elements in the development of LSI (Large Scale Integration) technology.

In normal planar MOS transistors, a channel extends in a horizontal direction along an upper surface of a semiconductor substrate. In contrast, a channel of SGTs extends in a vertical direction along an upper surface of a semiconductor substrate (see, for example, Japanese Patent Laid-Open No. 2-188966 and Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991)). Consequently, the SGTs allow higher packaging density of a semiconductor device than do the planar MOS transistors. The use of the SGTs as selection transistors allows greater packaging density of DRAMs (Dynamic Random Access Memories; see, for example, H. Chung, H. Kim, H. Kim, K. Kim, S. Kim, K. Dong, J. Kim, Y. C. Oh, Y. Hwang, H. Hong, G. Jin, and C. Chung: “4F2 DRAM Cell with Vertical Pillar Transistor (VPT),” 2011 Proceeding of the European Solid-State Device Research Conference, (2011)) connected with capacitors, PCMs (Phase Change Memories; see, for example, H. S. Philip Wong, S. Raoux, S. Kim, Jiale Liang, J. R. Reifenberg, B. Rajendran, M. Asheghi and K. E. Goodson: “Phase Change Memory,” Proceeding of IEEE, Vol. 98, No 12, December, pp. 2201-2227 (2010)) connected with variable resistance elements, RRAMs (Resistive Random Access Memories; see, for example, T. Tsunoda, K. Kinoshita, H. Noshiro, Y. Yamazaki, T. Iizuka, Y. Ito, A. Takahashi, A. Okano, Y. Sato, T. Fukano, M. Aoki, and Y. Sugiyama: “Low Power and High Speed Switching of Ti-doped NiO ReRAM under the Unipolar Voltage Source of less than 3V,” IEDM (2007)), and MRAMs (Magneto-resistive Random Access Memories; see, for example, W. Kang, L. Zhang, J. Klein, Y. Zhang, D. Ravelosona, and W. Zhao: “Reconfigurable Codesign of STT-MRAM Under Process Variations in Deeply Scaled Technology,” IEEE Transaction on Electron Devices, pp. 1-9 (2015) that varies resistance by changing magnetic spin direction by means of current. There is also a DRAM memory cell (see J. Wan, L. Rojer, A. Zaslaysky, and S. Critoloveanu: “A Compact Capacitor-Less High-Speed DRAM Using Field Effect-Controlled Charge Regeneration,” Electron Device Letters, Vol. 35, No. 2, pp. 179-181 (2012)) made up of a single MOS transistor without a capacitor. The present application relates to a dynamic flash memory that can be made up of MOS transistors without a variable resistance element or a capacitor.

FIGS. 10A to 10D show a write operation of the above-mentioned capacitorless DRAM memory cell made up of a single MOS transistor, FIGS. 11A and 11B show problems in operations, and FIGS. 12A to 12C show read operations (see, for example, J. Wan, L. Rojer, A. Zaslaysky, and S. Critoloveanu: “A Compact Capacitor-Less High-Speed DRAM Using Field Effect-Controlled Charge Regeneration,” Electron Device Letters, Vol. 35, No. 2, pp. 179-181 (2012); T. Ohsawa, K. Fujita, T. Higashi, Y. Iwata, T. Kajiyama, Y. Asao, and K. Sunouchi: “Memory design using a one-transistor gain cell on SOI,” IEEE JSSC, vol. 37, No. 11, pp1510-1522 (2002); T. Shino, N. Kusunoki, T. Higashi, T. Ohsawa, K. Fujita, K. Hatsuda, N. Ikumi, F. Matsuoka, Y. Kajitani, R. Fukuda, Y. Watanabe, Y. Minami, A. Sakamoto, J. Nishimura, H. Nakajima, M. Morikado, K. Inoh, T. Hamamoto, A. Nitayama: “Floating Body RAM Technology and its Scalability to 32 nm Node and Beyond,” IEEE IEDM (2006); and E. Yoshida: “A Capacitorless 1T-DRAM Technology Using Gate-Induced Drain-Leakage (GIDL) Current for Low-Power and High-Speed Embedded Memory,” IEEE IEDM (2006)). FIG. 10A shows a “1” written state. Here, the memory cell is formed on an SOI substrate 100, made up of a source N+ layer 103 (hereinafter a semiconductor region containing a high concentration of donor impurities will be referred to as an “N+ layer”) connected with a source line SL, a drain N+ layer 104 connected with a bit line BL, a gate conductive layer 105 connected with a word line WL, and a floating body 102 of a MOS transistor 102. That is, a DRAM memory cell is made up of a single MOS transistor without a capacitor. Note that a SiO₂ layer 101 of the SOI substrate is placed in contact with an undersurface of the floating body 102. When “1” is written into the memory cell made up of the single MOS transistor, the MOS transistor is operated in a saturation region. That is, an electron channel 107 extending from the source N⁺ layer 103 has a pinch-off point 108 and does not reach the drain N⁺ layer 104 connected with a bit line. If the MOS transistor is operated with a gate voltage set to approximately ½ a drain voltage by applying high voltages to the bit line BL connected to the drain N⁺ layer and the word line WL connected to the gate conductive layer 105 as described above, electric field strength is maximized at the pinch-off point 108 in the vicinity of the drain N⁺ layer 104. As a result, accelerated electrons flowing from the source N⁺ layer 103 towards the drain N⁺ layer 104 collide with a Si lattice, and electron-hole pairs are created by kinetic energy lost at that moment. Most of the generated electrons (not shown) reach the drain N⁺ layer 104. Only a few very hot electrons reach the gate conductive layer 105 by jumping over a gate oxide film 109. Positive holes 106 generated at the same time charge the floating body 102. In this case, the generated positive holes 106 contribute as an increment to majority carriers because the floating body 102 is made of p-type Si. The floating body 102 is filled with the generated positive holes 106, and if a voltage of the floating body 102 becomes higher than the source N⁺ layer 103 by Vb or more, positive holes generated further are discharged to the source N⁺ layer 103, where Vb is a built-in voltage of a pn junction between the source N⁺ layer 103 and the floating body 102 in a p-layer, and is approximately 0.7 V. FIG. 10B shows how the floating body 102 is charged to saturation by the generated positive holes 106.

Next, a “0” writing operation of a memory cell 110 will be described using FIG. 10C. There are a memory cell 110 that writes “1” and a memory cell 110 that writes “0” randomly to a common select word line WL. FIG. shows how a “1” written state is changed to a “0” written state. To write “0,” the voltage of bit line BL is negatively biased and a pn junction between the drain N⁺ layer 104 and the floating body 102 in the p-layer is forward biased. As a result, positive holes 106 generated in the floating body 102 beforehand in the previous cycle flows to the drain N⁺ layer 104 connected to the bit line BL. Once the write operation finishes, two states of the memory cell follow: a state in which the memory cell 110 is filled with the generated positive holes 106 (FIG. 10B) and a state in which the generated positive holes are discharged from the memory cell 110 (FIG. 10C). The floating body 102 of the memory cell 110 filled with the positive holes 106 is higher in potential than the floating body 102 free of generated positive holes. Therefore, a threshold voltage of the memory cell 110 written with “1” is lower than a threshold voltage of the memory cell 110 written with “0.” FIG. 10D shows how this looks like.

Next, problems in operations of the memory cell made up of a single MOS transistor will be described using FIGS. 11A and 11B. As shown in FIG. 11A, capacitance C_{FB} of the floating body is the sum total of capacitance C_{WL} between a gate connected with a word line and the floating body, junction capacitance C_{SL} of a pn junction between the source N⁺ layer 103 connected with a source line and the floating body 102, and junction capacitance C_{BL} of a pn junction between the drain N⁺ layer 104 connected with the bit line and the floating body 102; and is given by

C_{FB}=C_{WL}+C_{BL}+C_{SL} (8)

A capacitive coupling ratio β_{WL} between the gate connected with a word line and the floating body is given by

β_{WL}=C_{WL}/(C_{WL}+C_{BL}+C_{SL}) (9)

Therefore, if a word line voltage V_{WL} swings during reading or writing, a voltage of the floating body 102 serving as a memory node (contact) of the memory cell is also affected. FIG. 11B shows how this looks like. If a word line voltage V_{WL} rises from 0 V to V_{WLH} during reading or writing, a voltage V_{FB} of the floating body 102 rises from V_{FB1} to V_{FB2} due to capacitive coupling with the word line, where V_{FB1} is an initial voltage before the word line voltage changes. The amount of change ΔV_{FB} in voltage is given by

ΔV_{FB}=V_{FB2}−V_{FB1}=β_{WL}×V_{WLH} (10)

In β_{WL} in Eq. (9), a contribution ratio of C_{WL} is large, and is expressed, for example, by C_{WL}:C_{BL}:C_{SL}, =8:1:1. In this case, β_{WL}=0.8. If the word line, for example, is 5 V during writing and 0 V after the end of writing, due to capacitive coupling of the word line WL and floating body 102, the floating body 102 is subjected to amplitude noise as high as 5 V×β_{WL}=4 V. This poses a problem in that a sufficient margin of potential difference between a logic 1 potential and logic 0 potential of the floating body 102 cannot be secured during writing.

FIGS. 12A to 12C show a read operation, where FIG. 12A shows a “1” written state and FIG. 12B shows a “0” written state. Actually, however, even if Vb is written into the floating body 102 by writing of “1,” if the word line returns to 0 V when the writing is finished, the floating body 102 is lowered to a negative bias. When “0” is being written, because the floating body 102 is negatively biased further, a sufficiently large margin of potential difference cannot be secured between “1” and “0” as shown in FIG. 12C, making it difficult to commercially introduce really capacitorless DRAM memory cells.

A capacitorless single-transistor DRAM (gain cell) has a problem in that there is large capacitive coupling between a word line and a floating body and if potential of the word line swings during data read or write, the swings are transmitted as noise to the floating body. This causes misreading or erroneous rewriting of storage data, making it difficult to put the capacitorless single-transistor DRAM (gain cell) to practical use.

### SUMMARY OF THE INVENTION

To solve the above problem, a semiconductor element memory device according to the present invention comprises a first block in which a plurality of first memory cells is arrayed in a matrix; and first and second semiconductor elements included in the first memory cells, each of the first and second semiconductor elements in turn including: a semiconductor base body erected on a substrate in a vertical direction of the substrate or extended on the substrate in a horizontal direction, a first impurity region and a second impurity region provided on opposite ends of the semiconductor base body; a gate insulating layer placed in contact with a lateral surface of the semiconductor base body between the first impurity region and the second impurity region; a first gate conductor layer covering part or all of the gate insulating layer; and a second gate conductor layer located adjacent to the first gate conductor layer and placed in contact with a lateral surface of the gate insulating layer, wherein positive hole groups generated by an impact ionization phenomenon or by a gate-induced drain leakage current are held in the semiconductor base body by controlling voltages applied to the first gate conductor layer, the second gate conductor layer, the first impurity region, and the second impurity region, of the first semiconductor elements of the first memory cells, the first impurity region is connected with a source line, the second impurity region is connected with a first bit line, and one of the first gate conductor layer and the second gate conductor layer is connected with a word line and another is connected with a drive control line, and of the second semiconductor elements of the first memory cells, the first impurity region is connected with the source line, the second impurity region is connected with a second bit line, and one of the first gate conductor layer and the second gate conductor layer is connected with the word line, and another is connected with the drive control line (first aspect).

In the first aspect of the present invention, during a data write operation, one of a voltage of the semiconductor base body of the first semiconductor elements and a voltage of the semiconductor base body of the second semiconductor elements serves as a first data retention voltage, and another serves as a second data retention voltage (second aspect).

In the first aspect of the present invention, each of the first memory cells has a capacity of 1 bit (third aspect).

In the first aspect of the present invention, the first bit line and the second bit line are connected to a dynamic sense amplifier circuit to read data from the first memory cells and write data to the first memory cells via the dynamic sense amplifier circuit (fourth aspect).

In the first aspect of the present invention, the first bit line and the second bit line are connected to a differential amplifier circuit to read data from the first memory cells via the differential amplifier circuit (fifth aspect).

In the first aspect of the present invention, the first block is mounted in a mixture with other elements on a logic chip (sixth aspect).

In the first aspect of the present invention, the semiconductor memory device further comprises a second block in which a plurality of second memory cells is arrayed in a matrix, wherein the second memory cells include the first semiconductor elements or second semiconductor elements as semiconductor elements; of the semiconductor elements of the second memory cells, the first impurity region is connected with a source line, the second impurity region is connected with a bit line, and one of the first gate conductor layer and the second gate conductor layer is connected with a word line and another is connected with a drive control line; and
the second block is mounted in a mixture with the first block on a memory chip (seventh aspect).

In the first aspect of the present invention, one or both of the first gate conductor layer and the second gate conductor layer are divided into two or more separate gate conductor layers in planar view or in a vertical direction and the separate gate conductor layers are operated synchronously or asynchronously (eighth aspect).

In the eighth aspect of the present invention, in the vertical direction, either the separate gate conductor layers of the first gate conductor layer are placed on opposite sides of the second gate conductor layer, or the separate gate conductor layers of the second gate conductor layer are placed on opposite sides of the first gate conductor layer (ninth aspect).

### BRIEF DESCRIPTION OF THE DRAWINGS

FIG. 1 is a structural diagram of a memory device having an SGT according to a first embodiment;

FIGS. 2A, 2B and 2C are diagrams explaining effects produced when gate capacitance of a first gate conductor layer 5a connected to a plate line PL of the memory device having the SGT according to the first embodiment is made higher than gate capacitance of a second gate conductor layer 5b connected with a word line WL;

FIGS. 3A, 3B, 3C and 3D are diagrams for explaining a write operation mechanism of the memory device having the SGT according to the first embodiment;

FIGS. 4AA, 4AB and 4AC are diagrams for explaining an erase operation mechanism of the memory device having the SGT according to the first embodiment;

FIG. 4B is a diagram for explaining the erase operation mechanism of the memory device having the SGT according to the first embodiment;

FIGS. 5A, 5B and 5C are diagrams for explaining a read operation mechanism of the memory device having the SGT according to the first embodiment;

FIG. 6A is a diagram for explaining high-speed dynamic flash memory cell technology of the memory device having the SGT according to the first embodiment;

FIGS. 6BA, 6BB and 6BC are diagrams for explaining the high-speed dynamic flash memory cell technology of the memory device having the SGT according to the first embodiment;

FIG. 6C is a diagram for explaining the high-speed dynamic flash memory cell technology of the memory device having the SGT according to the first embodiment;

FIG. 6D is a diagram for explaining the high-speed dynamic flash memory cell technology of the memory device having the SGT according to the first embodiment;

FIG. 6E is a diagram for explaining the high-speed dynamic flash memory cell technology of the memory device having the SGT according to the first embodiment;

FIG. 6F is a diagram for explaining the high-speed dynamic flash memory cell technology of the memory device having the SGT according to the first embodiment;

FIG. 6G is a diagram for explaining the high-speed dynamic flash memory cell technology of the memory device having the SGT according to the first embodiment;

FIG. 6H is a diagram for explaining the high-speed dynamic flash memory cell technology of the memory device having the SGT according to the first embodiment;

FIG. 7A is a diagram for explaining a sense amplifier circuit of a high-speed dynamic flash memory cell of a memory device having an SGT according to a second embodiment;

FIG. 7B is a diagram for explaining the sense amplifier circuit of the high-speed dynamic flash memory cell of the memory device having the SGT according to the second embodiment;

FIG. 8A is a diagram for explaining a memory array of a memory device having an SGT according to a third embodiment;

FIG. 8B is a diagram for explaining the memory array of the memory device having then SGT according to the third embodiment;

FIGS. 9AA, 9AB and RAC are diagrams for explaining an application chip of a high-speed dynamic flash memory cell of a memory device having an SGT according to a fourth embodiment;

FIGS. 9BA, and 9BB are diagrams for explaining the application chip of the high-speed dynamic flash memory cell of the memory device having the SGT according to the fourth embodiment;

FIGS. 10A, 10B, 10C and 10D are diagrams for explaining a write operation of a capacitorless DRAM memory cell according to a conventional example;

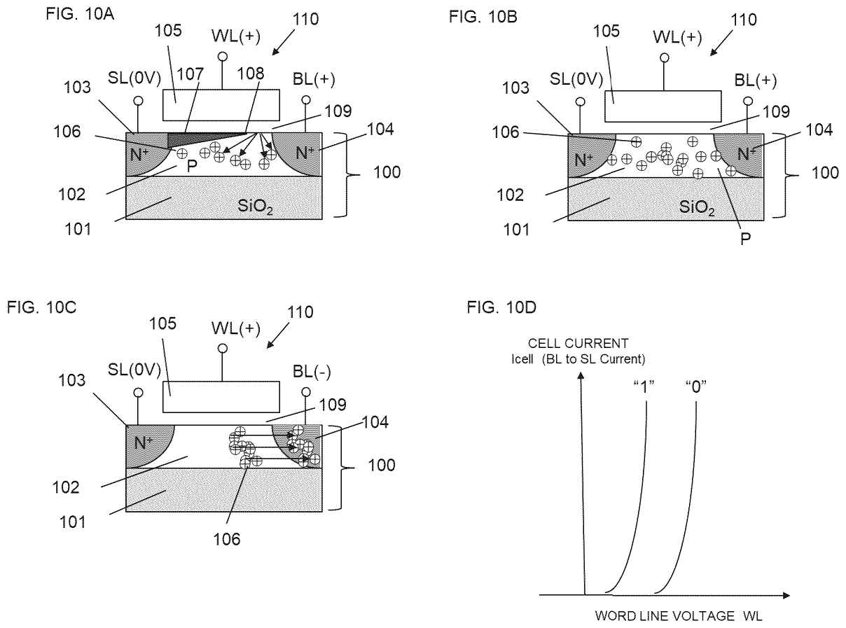

FIGS. 11A and 11B are diagrams for explaining problems in operations of the capacitorless DRAM memory cell according to the conventional example; and

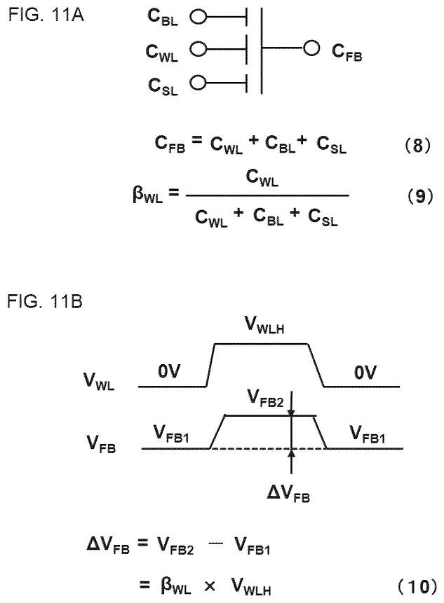

FIGS. 12A, 12B and 12C are diagrams for explaining a read operation of the capacitorless DRAM memory cell according to the conventional example.

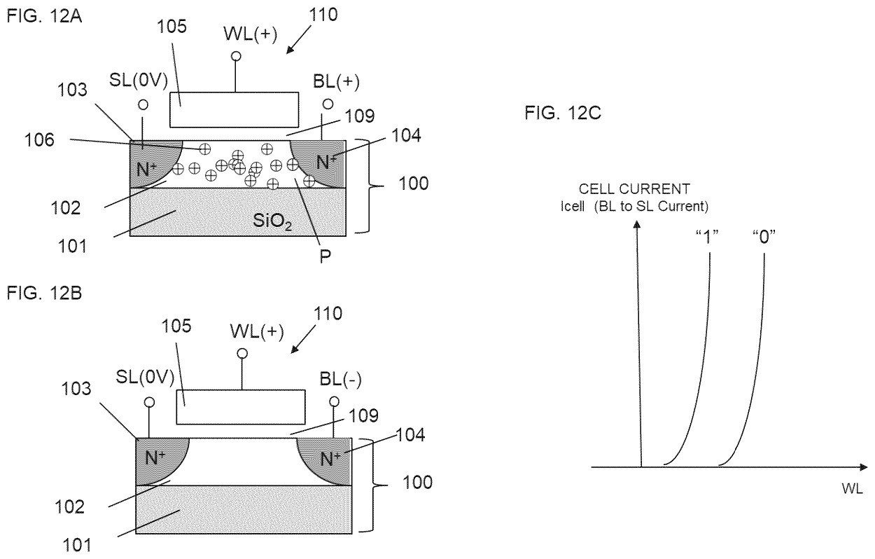

### DETAILED DESCRIPTION OF THE PREFERRED EMBODIMENTS

Embodiments of a memory device (hereinafter referred to as a dynamic flash memory), which uses a semiconductor element, according to the present invention will be described below with reference to the drawings.

### First Embodiment

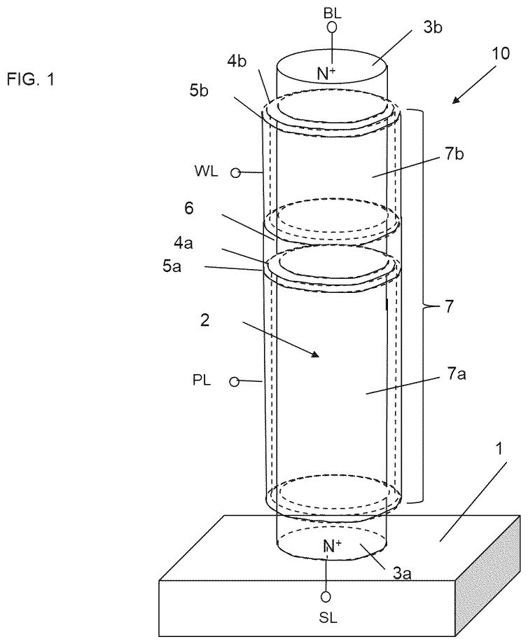

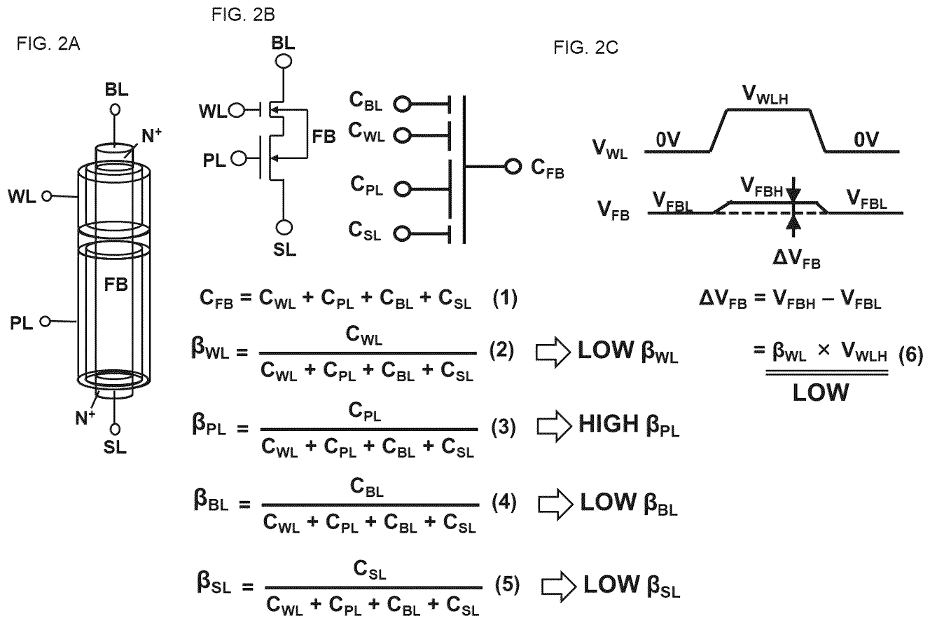

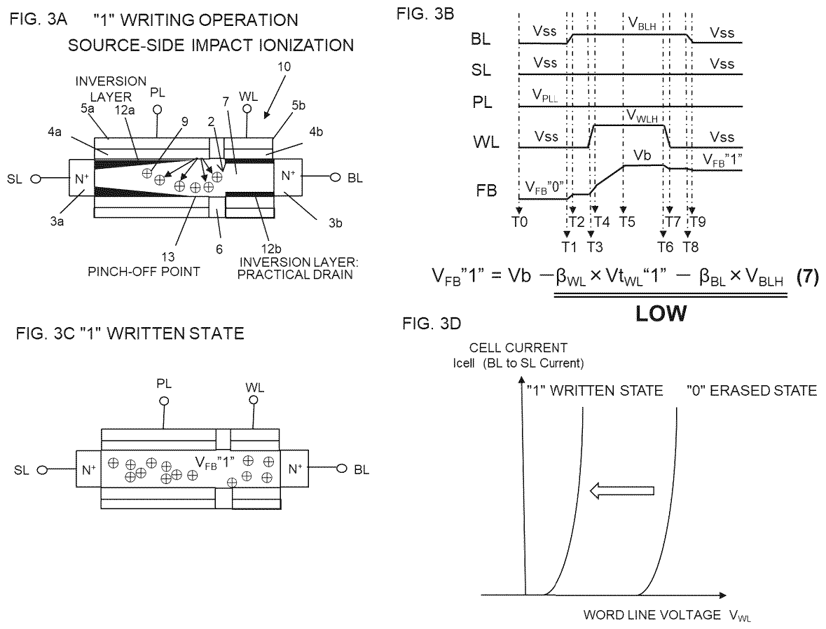

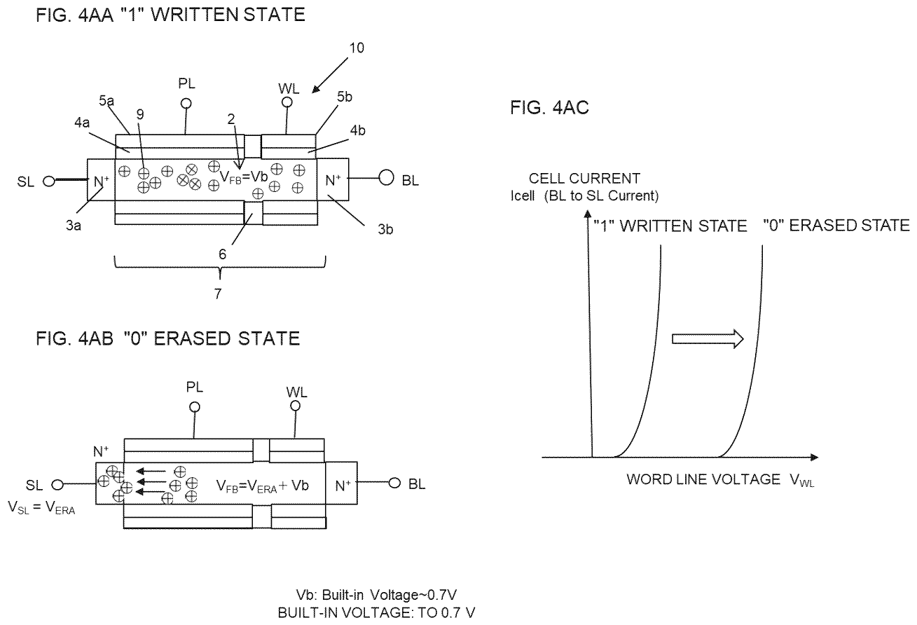

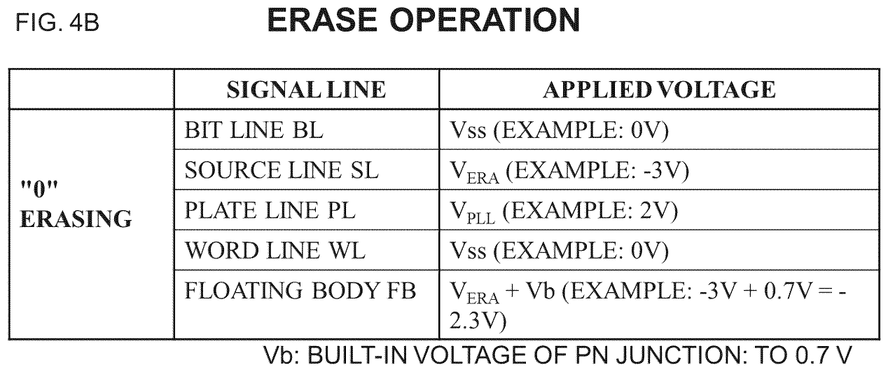

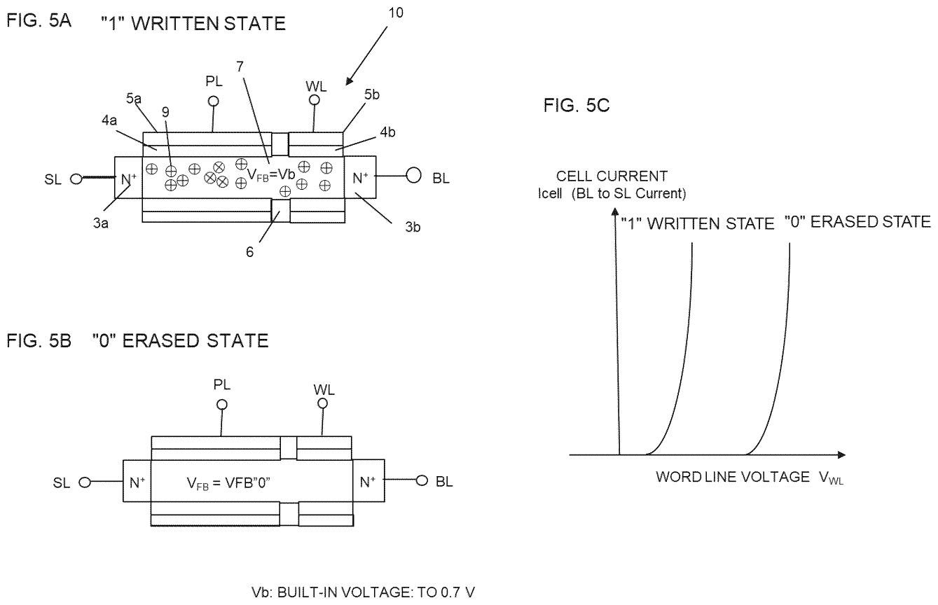

A structure and operation mechanism of a dynamic flash memory cell according to a first embodiment of the present invention will be described below using FIGS. 1 to 6H. The structure of the dynamic flash memory cell will be described using FIG. 1. Then, using FIGS. 2A to 2C, description will be given of effects produced when gate capacitance of a first gate conductor layer 5a connected to a plate line PL is made higher than gate capacitance of a second gate conductor layer 5b connected with a word line WL. Then, a data write operation mechanism will be described using FIGS. 3A to 3D, a data erase operation mechanism will be described using FIGS. 4AA to 4B, and a data read operation mechanism will be described using FIGS. 5A to 5C.

The structure of the dynamic flash memory cell according to the first embodiment of the present invention is shown in FIG. 1. N⁺ layers 3a and 3b (which are examples of a “first impurity region” and a “second impurity region” described in Claims), one of which serves as a source while the other serves as a drain, are formed at upper and lower positions in a silicon semiconductor pillar 2 (which is an example of a “semiconductor base body” described in Claims, and will be referred to hereinafter as a “Si pillar”) formed on a substrate 1 (which is an example of a “substrate” described in Claims) and having a P or i conductivity type (intrinsic type). That part of the Si pillar 2 which is between the N⁺ layers 3a and 3b that serve as the source and the drain is a semiconductor base body 7. A first gate insulating layer 4a (which is an example of a “first gate insulating layer” described in Claims) and a second gate insulating layer 4b (which is an example of a “second gate insulating layer” described in Claims) are formed by surrounding the semiconductor base body 7. The first gate insulating layer 4a and the second gate insulating layer 4b are placed, respectively, in contact with, or close to, the N⁺ layers 3a and 3b that serve as the source and the drain. The first gate conductor layer (which is an example of a “first gate conductor layer” described in Claims) and the second gate conductor layer (which is an example of a “second gate conductor layer” described in Claims) are formed by surrounding the first gate insulating layer 4a and the second gate insulating layer 4b, respectively. The first gate conductor layer 5a and the second gate conductor layer 5b are separated by an insulating layer 6 (which is an example of a “first insulating layer” described in Claims). The semiconductor base body 7 (which is an example of a “semiconductor base body” described in Claims), which is that part of the Si pillar 2 which is between the N⁺ layers 3a and 3b, is made up of a first channel Si layer 7a surrounded by the first gate insulating layer 4a (which is an example of a “first semiconductor base body” described in Claims) and a second channel Si layer 7b (which is an example of a “second semiconductor base body” described in Claims) surrounded by the second gate insulating layer 4b. This results in formation of a dynamic flash memory cell 10 made up of the N⁺ layers 3a and 3b, which are to become the source and the drain, the semiconductor base body 7, the first gate insulating layer 4a, the second gate insulating layer 4b, the first gate conductor layer 5a, and the second gate conductor layer 5b. Then, the N⁺ layer 3a to become the source is connected to a source line SL (which is an example of a “source line” described in Claims), the N⁺ layer 3b to become the drain is connected to a bit line BL, the first gate conductor layer 5a is connected to the plate line PL, which is a drive control line (which is an example of a “drive control line” described in Claims), and the second gate conductor layer 5b is connected to the word line WL (which is an example of a “word line” described in Claims). Desirably the gate capacitance of the first gate conductor layer 5a connected with the plate line PL is structured to be higher than the gate capacitance of the second gate conductor layer 5b connected with the word line WL.

Note that in FIG. 1, the first gate conductor layer 5a is made larger in gate length than the second gate conductor layer 5b such that the first gate conductor layer 5a connected to the plate line PL will be higher in gate capacitance than the second gate conductor layer 5b connected with the word line WL. In addition, however, instead of making the first gate conductor layer 5a larger in gate length than the second gate conductor layer 5b, film thicknesses of the gate insulating layers may be changed such that a gate insulating film of the first gate insulating layer 4a will be smaller in film thickness than a gate insulating film of the second gate insulating layer 4b. Also, materials of the gate insulating layers may be varied in permittivity such that the gate insulating film of the first gate insulating layer 4a will be higher in permittivity than the gate insulating film of the second gate insulating layer 4b. Besides, the first gate conductor layer 5a connected to the plate line PL may be made higher in gate capacitance than the second gate conductor layer 5b connected with the word line WL by combining any of the following: lengths of the gate conductor layers 5a and 5b, and film thicknesses and permittivities of the gate insulating layers 4a and 4b.

FIGS. 2A to 2C are diagrams explaining effects produced when the gate capacitance of the first gate conductor layer 5a connected to the plate line PL is made higher than the gate capacitance of the second gate conductor layer 5b connected with the word line WL.

FIG. 2A shows only main part of the dynamic flash memory cell according to the first embodiment of the present invention in a simplified manner. The dynamic flash memory cell is connected with the bit line BL, the word line WL, the plate line PL, and the source line SL, whose voltage states determine a potential state of the semiconductor base body 7.

FIG. 2B is a diagram for explaining relationships among capacitances. Capacitance C_{FB} of the semiconductor base body 7 is the sum total of capacitance C_{WL} between the gate conductor layer 5b connected with the word line WL and the semiconductor base body 7, capacitance C_{PL} between the gate conductor layer 5a connected with the plate line PL and the semiconductor base body 7, junction capacitance C_{SL}, of a pn junction between the source N⁺ layer 3a connected with the source line SL and the semiconductor base body 7, and junction capacitance C_{BL} of a pn junction between the drain N⁺ layer 3b connected with the bit line BL and the semiconductor base body 7, and is given by

C_{FB}=C_{WL}+C_{PL}+C_{BL}+C_{SL} (1)

Therefore, a coupling ratio β_{WL} between the word line WL and the semiconductor base body 7, a coupling ratio β_{PL} between the plate line PL and the semiconductor base body 7, a coupling ratio β_{BL} between the bit line BL and the semiconductor base body 7, and a coupling ratio β_{SL} between the source line SL and the semiconductor base body 7 are given, respectively, by

β_{WL}=C_{WL}/(C_{WL}+C_{PL}+C_{BL}+C_{SL}) (2)

β_{PL}=C_{PL}/(C_{WL}+C_{PL}+C_{BL}+C_{SL}) (3)

β_{BL}=C_{BL}/(C_{WL}+C_{PL}+C_{BL}+C_{SL}) (4) and

β_{SL}=C_{SL}/(C_{WL}+C_{PL}+C_{BL}+C_{SL}) (5),

where C_{PL}>C_{WL}, and thus β_{PL}>β_{WL}.

FIG. 2C is a diagram for explaining changes of a voltage V_{FB} in the semiconductor base body 7 when a voltage V_{WL} of the word line WL rises during read and write operations and falls subsequently. Here, when the voltage V_{WL} of the word line WL rises from 0 V to a high-voltage state V_{WLH} and the voltage V_{FB} of the semiconductor base body 7 changes from a low-voltage state V_{FBL} to a high-voltage state V_{FBH}, a potential difference ΔV_{FB} is given by

ΔV_{FB}=V_{FBH}−V_{FBL}=β_{WL}×V_{WLH} (6)

Because the coupling ratio NI, between the word line WL and the semiconductor base body 7 is low and the coupling ratio β_{FL} between the plate line PL and the semiconductor base body 7 is high, ΔV_{FB} is low and even if the voltage V_{WL} of the word line WL rises and falls during read and write operations, the voltage V_{FB} of the semiconductor base body 7 almost does not change.

A write operation of the dynamic flash memory cell according to the first embodiment of the present invention is shown in FIGS. 3A to 3D. FIG. 3A shows a mechanism of the write operation and FIG. 3B shows operation waveforms of the bit line BL, source line SL, plate line PL, word line WL, and semiconductor base body 7, which is indicated as the floating body FB. At time T0, the dynamic flash memory cell is in a “0” erased state and the voltage of the semiconductor base body 7 is V_{FB} “0.” Besides, Vss is applied to the bit line BL, the source line SL, and the word line WL while V_{PLL} is applied to the plate line PL. Here, for example, Vss is 0 V and V_{PLL} is 2 V. Next, from time T1 to time T2, when the bit line BL rises from Vss to V_{BLH}, for example, if Vss is 0 V, the voltage of the semiconductor base body 7 becomes V_{FB} “0”+β_{BL}×V_{BLH} as a result of capacitive coupling between the bit line BL and the semiconductor base body 7.

Next, a write operation of the dynamic flash memory cell will be described using FIGS. 3A and 3B. From time T3 to time T4, the voltage of the word line WL rises from Vss to V_{WLH}. Consequently, when the second gate conductor layer 5b connected with the word line WL sets a “0” erasing threshold voltage of a second n-channel MOS transistor region surrounding the semiconductor base body 7 to Vt_{WL} “0,” as the voltage of the word line WL rises, from Vss to Vt_{WL} “0,” the voltage of the semiconductor base body 7 becomes V_{FB} “0”+β_{BL}×V_{BLH}+β_{WL}×Vt_{WL} “0” as a result of capacitive coupling between the word line WL and the semiconductor base body 7. If the voltage of the word line WL rises to or above Vt_{WL} “0,” an annular inversion layer 12b is formed in the semiconductor base body 7 inside the second gate conductor layer 5b, blocking capacitive coupling between the word line WL and the semiconductor base body 7.

Description of the write operation of the dynamic flash memory cell will be continued using FIGS. 3A and 3B. From time T3 to time T4, for example, V_{PLL}=2 V is inputted constantly to the first gate conductor layer 5a connected with the plate line PL, raising the second gate conductor layer 5b connected with the word line WL to, for example, V_{WLH}=4 V. Consequently, as shown in FIG. 3A, an annular inversion layer 12a is formed on the semiconductor base body 7 inside the first gate conductor layer 5a connected with the plate line PL, with a pinch-off point 13 existing in the inversion layer 12a. As a result, a first n-channel MOS transistor region having the first gate conductor layer 5a operates in a saturation region. On the other hand, the second re-channel MOS transistor region having the second gate conductor layer 5b that is connected with the word line WL operates in a linear region. As a result, no pinch-off point exists in the semiconductor base body 7 inside the second gate conductor layer 5b connected with the word line WL, and an inversion layer 12b is formed on the entire surface. The inversion layer 12b formed on the entire inner circumference of the second gate conductor layer 5b connected with the word line WL operates as a practical drain of the second n-channel MOS transistor region having the second gate conductor layer 5b. As a result, an electric field is maximized and an impact ionization phenomenon occurs in a first boundary region of the semiconductor base body 7 between the first re-channel MOS transistor region having the first gate conductor layer 5a that is connected in series and the second n-channel MOS transistor region having the second gate conductor layer 5b. The first boundary region is a source-side region as viewed from the second n-channel MOS transistor region having the second gate conductor layer 5b that is connected with the word line WL, and thus the phenomenon is called a source-side impact ionization phenomenon. As a result of the source-side impact ionization phenomenon, electrons flow from the N⁺ layer 3a connected with the source line SL toward the N⁺ layer 3b connected with the bit line. Accelerated electrons collide with Si lattice atoms and electron-hole pairs are created by kinetic energy of the accelerated electrons. Part of the generated electrons flows to the first gate conductor layer 5a and the second gate conductor layer 5b, but most of the electrons flow to the N⁺ layer 3b connected to the bit line BL (not shown).

As shown in FIG. 3C, generated positive hole groups 9 (which are examples of a “positive hole group” described in Claims) are majority carriers in the semiconductor base body 7 and charge the semiconductor base body 7 so as to be positively biased. The N⁺ layer 3a connected with the source line SL is 0 V and thus the semiconductor base body 7 is charged to a built-in voltage Vb (approximately 0.7 V) of a pn junction between the N⁺ layer 3a connected with the source line SL and the semiconductor base body 7. Once the semiconductor base body 7 is charged to be positively biased, threshold voltages of the first n-channel MOS transistor region and second n-channel MOS transistor region fall due to a substrate bias effect.

Description of the write operation of the dynamic flash memory cell will be continued using FIG. 3B. From time T6 to time T7, the voltage of the word line WL drops from V_{WLH} to Vss. In so doing, the word line WL and the semiconductor base body 7 form capacitive coupling, but until the voltage V_{WLH} of the word line WL becomes equal to or lower than the threshold voltage Vt_{WL} “1” of the second n-channel MOS transistor region when the voltage of the semiconductor base body 7 is Vb, the inversion layer 12b blocks the capacitive coupling. Therefore, practical capacitive coupling between the word line WL and the semiconductor base body 7 is enabled only when the word line WL becomes equal to or lower than Vt_{WL} “1” and falls to Vss. As a result, the voltage of the semiconductor base body 7 becomes Vb−β_{WL}×Vt_{WL} “1.” Here, Vt_{WL} “1” is lower than Vt_{WL} “0” described above, and thus β_{WL}×Vt_{WL} “1” is low.

Description of the write operation of the dynamic flash memory cell will be continued using FIG. 3B. From time T8 to time T9, the bit line BL drops from V_{BLH} to Vss. Since the bit line BL and the semiconductor base body 7 are capacitively coupled, eventually “1”-writing voltage V_{FB} “1” of the semiconductor base body 7 becomes as follows.

V_{FB}“1”=Vb−β_{WL}×Vt_{WL}“1”−β_{BL}×V_{BLH} (7),

where the coupling ratio β_{BL} between the bit line BL and the semiconductor base body 7 is also low. Consequently, as shown in FIG. 3D, the threshold voltage of the second n-channel MOS transistor region of a second semiconductor base body 7b connected with the word line WL becomes low. A “1” written state of the semiconductor base body 7 is set to a first data retention voltage (which is an example of a “first data retention voltage” described in Claims). A memory write operation (which is an example of a “data write operation” described in Claims) is performed and this state is assigned to logical storage data “1.”

Note that in the write operation, electron-hole pairs may be generated by an impact ionization phenomenon in a second boundary region between a first impurity region 3a and a first semiconductor base body 7a or in a third boundary region between a second impurity region 3b and a second semiconductor base body 7b rather than in the first boundary region, and the semiconductor base body 7 may be charged with the generated positive hole groups 9.

A memory erase operation mechanism will be described using FIGS. 4AA to 4AC and 4B. The semiconductor base body 7 between the N⁺ layers 3a and 3b is electrically separated from the substrate, making up a floating body. FIG. 4AA shows that before the erase operation, the positive hole groups 9 generated by impact ionization in the previous cycle are stored in the semiconductor base body 7. As shown in FIG. 4AB, during an erase operation, the voltage of the source line SL is set to a negative voltage V_{ERA}. Here, V_{ERA} is, for example, −3 V. Consequently, regardless of the value of an initial potential of the semiconductor base body 7, the pn junction between the N⁺ layer 3a connected with the source line SL to serve as a source and the semiconductor base body 7 becomes forward-biased. As a result, the positive hole groups 9 generated by impact ionization in the previous cycle and stored in the semiconductor base body 7 are drawn into the N⁺ layer 3a in a source area, a potential V_{FB} of the semiconductor base body 7 becomes V_{FB}=V_{ERA}+Vb, and the resulting voltage value becomes a second data retention voltage (which is an example of a “second data retention voltage” described in Claims). Here, Vb is the built-in voltage of the pn junction and is approximately 0.7 V. Therefore, when V_{ERA}=−3 V, the potential of the semiconductor base body 7 becomes −2.3 V. This value is the potential state of the semiconductor base body 7 in an erased state. Therefore, when a potential of the semiconductor base body 7 of the floating body becomes a negative voltage, the threshold voltage of the second n-channel MOS transistor region increases due to the substrate bias effect. Consequently, as shown in FIG. 4AC, a threshold voltage of the second gate conductor layer 5b connected with the word line WL increases. The erased state of the semiconductor base body 7 turns to “0” of logical storage data. Note that an example of voltage conditions for major node contacts during the erase operation is shown in FIG. 4B.

FIGS. 5A to 5C are diagrams for explaining a read operation of the dynamic flash memory cell according to the first embodiment of the present invention. As shown in FIG. 5A, when the semiconductor base body 7 is charged to the built-in voltage Vb (approximately 0.7 V), the threshold voltage of the second n-channel MOS transistor region having the second gate conductor layer 5b that is connected with the word line WL drops due to the substrate bias effect. This state is assigned to logical storage data “1.” As shown in FIG. 5B, a memory block selected before a write is set to an erased state “0” in advance and the voltage V_{FB} of the semiconductor base body 7 is V_{FB} “0.” As a result of write operations, a written state “1” is stored randomly. As a result, logical storage data of logic “0” and logic “1” is created for the word line WL. As shown in FIG. 5C, using a height difference between two threshold voltages for the word line WL, reading is done by a sense amplifier. During the data read, if the voltage to be applied to the first gate conductor layer 5a joined to the plate line PL is set higher than the threshold voltage at a time when the logical storage data is “1” and lower than the threshold voltage at a time when the logical storage data is “0,” the property that no current flows even if the voltage of the word line WL is increased is obtained.

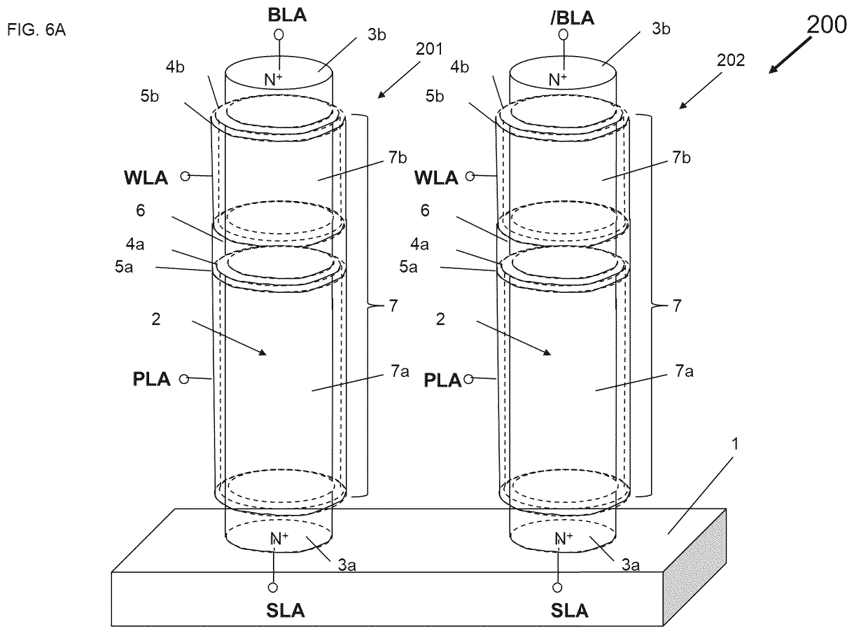

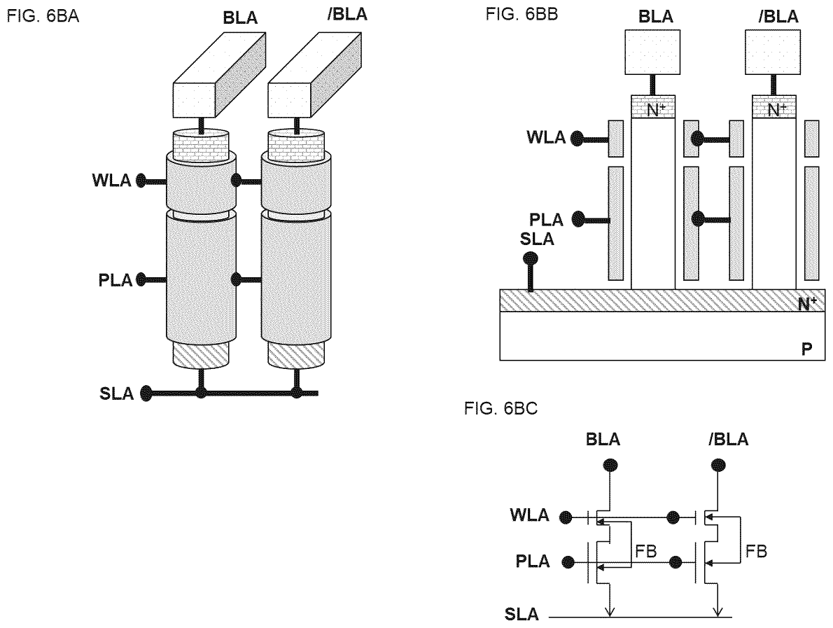

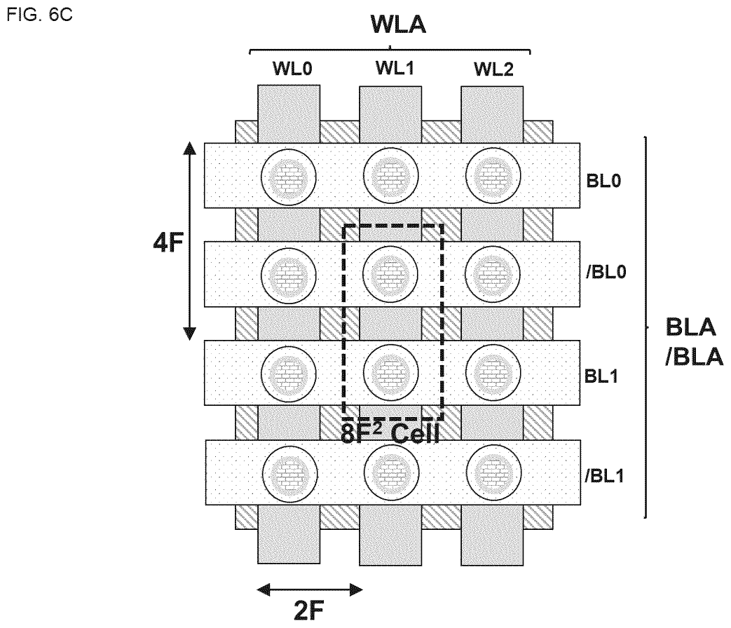

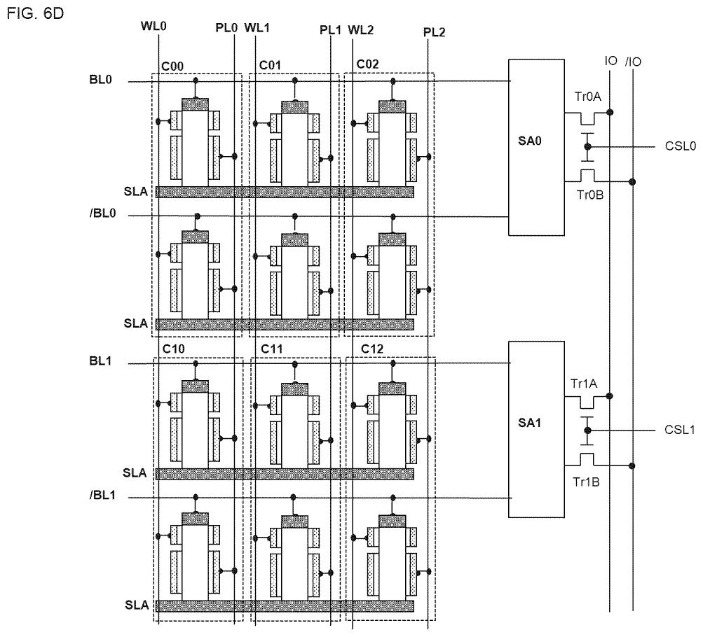

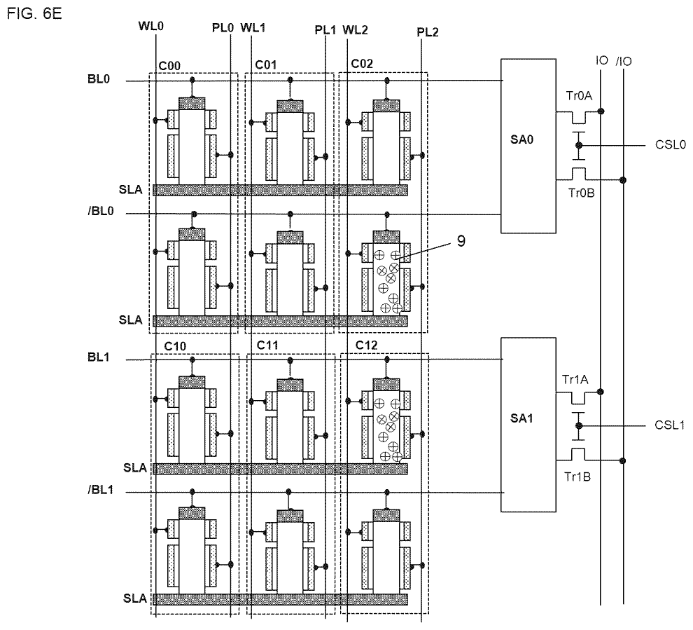

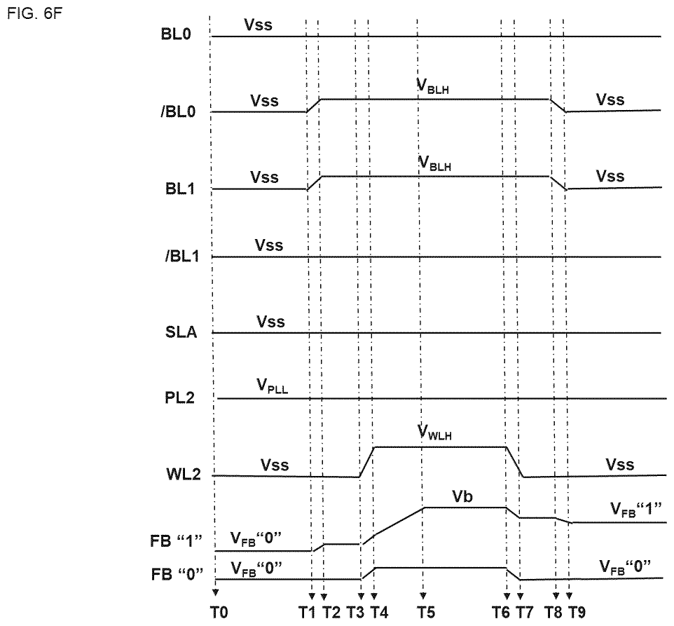

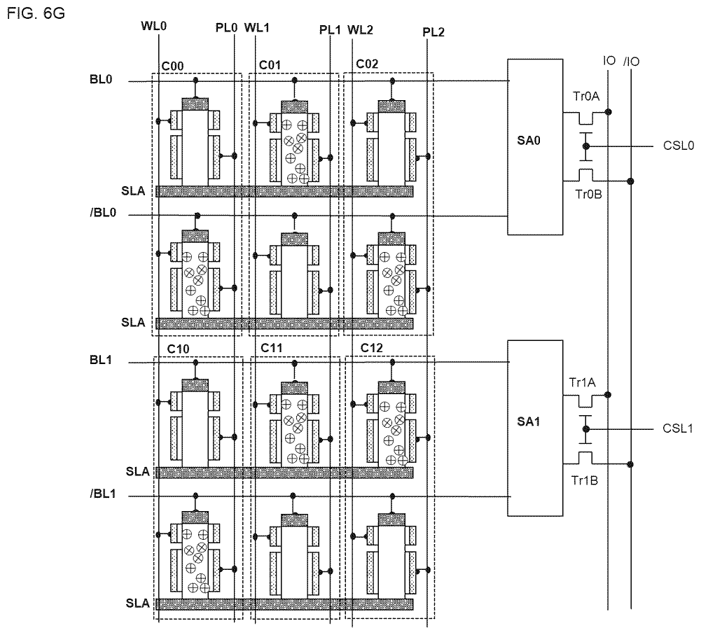

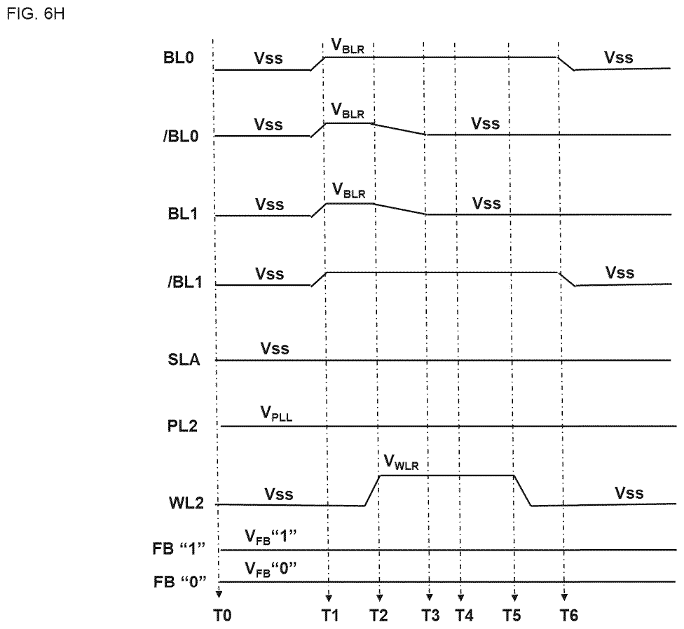

FIGS. 6A to 6H are diagrams for explaining high-speed dynamic flash memory cell technology according to the first embodiment of the present invention.

FIG. 6A shows the structure of the high-speed dynamic flash memory cell according to the first embodiment of the present invention. Regarding the high-speed dynamic flash memory cell, one first memory cell 200 (which is an example of a “first memory cell” described in Claims) is constructed using two pieces of the semiconductor base body for the dynamic flash memory cell according to the first embodiment of the present invention described in FIG. 1. The first impurity region 3a of first semiconductor base body 201 for the first memory cell 200 is connected with a source line SLA (which is an example of the “source line” described in Claims), the second impurity region 3b is connected with a first bit line BLA (which is an example of a “first bit line” described in Claims), the first gate conductor layer 5a is connected with a plate line PLA (which is an example of the “drive control line” described in Claims), which is a drive control line, and the second gate conductor layer 5b is connected with a word line WLA (which is an example of the “word line” described in Claims). The first impurity region 3a of second semiconductor base body 202 for the first memory cell 200 is connected with a source line SLA, the second impurity region 3b is connected with a second bit line/BLA (which is an example of a “second bit line” described in Claims), the first gate conductor layer 5a is connected with a plate line PLA, which is a drive control line, and the second gate conductor layer 5b is connected with a word line WLA.

FIGS. 6BA to 6BC show a bird's-eye view, a sectional view, and an equivalent circuit diagram, respectively, of a 1-bit (which is an example of “1 bit” described in Claims) high-speed dynamic flash memory cell made up of two semiconductor base bodies. In FIGS. 6BA to 6BC, the high-speed dynamic flash memory cell is connected with the first bit line BLA, the second bit line/BLA, the source line SLA, the plate line PLA, and the word line WLA.

FIG. 6C shows a plan view of a first block (which is an example of a “first block” described in Claims) in which multiple, i.e., 3 by 2, high-speed dynamic flash memory cells are arrayed in a matrix (which is an example of “in a matrix” described in Claims). The high-speed dynamic flash memory cells can be arrayed by setting the total pitch of the first bit line BLA and the second bit line/BLA to 4F, the pitch of the word line WLA to 2F, and the 1-bit memory cell size to 4F×2F=8F², where F is feature size, which is one of design rules or ground rules. In a miniaturized dynamic flash memory cell, for example, F=15 nm. In this example, spacing between the first bit line BLA and the second bit line/BLA is only 15 nm, but the first bit line BLA and the second bit line /BLA are capable of high-speed read operations in order to transmit complementary signals to a sense amplifier circuit.

FIG. 6D shows a circuit block diagram of the first block in which 3×2 high-speed dynamic flash memory cells C00 to C12 of FIG. 6C are arrayed in a matrix. The high-speed dynamic flash memory cells C00 to C12 are connected with first bit lines BL0 and BL1, second bit lines /BL0 and /BL1, the source line SLA, word lines WL0 to WL2, and plate lines PL0 to PL2. Each bit line pair is connected with sense amplifier circuits SA0 and SA1. The sense amplifier circuits SA0 and SA1 are connected to input-output lines IO and /IO via transistors Tr0A to Tr1B, whose gates are connected with column selection lines CSL0 and CSL1. Besides, the “0” erasing operation described, for example, in FIGS. 4AA to 4B is performed in the first block shown in FIG. 6D, and positive hole groups 9 generated by impact ionization in the semiconductor base bodies 7 do not exist in any of the memory cells.

First, differences among the “0” erasing operation, data “1” writing operation, and data “0” writing operation will be described. To begin with, during the “0” erasing operation, since the “0” erasing operation described, for example, in FIGS. 4AA to 4B are performed, positive hole groups 9 in the semiconductor base bodies 7 do not exist in the first semiconductor base body 201 and second semiconductor base body 202 making up the first memory cell 200. Then, in the “0” erased state, a data “1” writing operation and a data “0” writing operation are performed. In the data “1” writing operation, the first bit line BLA is raised from low voltage Vss to high voltage V_{BLH} and positive hole groups 9 are left, for example, by the impact ionization phenomenon in the semiconductor base bodies 7 of the first semiconductor base body 201 for the first memory cell 200. On the other hand, in the data “0” writing operation, the second bit line /BLA is raised from low voltage Vss to high voltage V BLH and positive hole groups 9 are left, for example, by the impact ionization phenomenon in the semiconductor base bodies 7 of the second semiconductor base body 202 for the first memory cell 200. In this way, the data “1” writing operation involves the first bit line BLA, and the data “0” writing operation involves the second bit line /BLA.

Next, the data write operation (which is an example of the “data write operation” described in Claims) of the high-speed dynamic flash memory cell will be described. FIG. 6E shows a circuit block diagram of the write operation of the first block in which 3×2 high-speed dynamic flash memory cells C00 to C12 are arrayed in a matrix while FIG. 6F shows an operation waveform diagram of the write operation of the high-speed dynamic flash memory cell. The write operation is performed, for example, by the method described in FIGS. 3A to 3D. Description will also be given of a case in which, for example, the word line WL2 is selected and data write operations are performed to write data “0” into a memory cell C02 and to write data “1” into the memory cell C12. The sense amplifier circuits SA0 and SA1 are, for example, dynamic sense amplifier circuits (which are an example of a “dynamic sense amplifier circuit” described in Claims), which have been loaded with write data in advance via the input-output lines IO and /IO.

Description of an example of the data write operation of the high-speed dynamic flash memory cell will be continued using FIGS. 6E and 6F. From time T1 to time T2, the second bit line /BL0 and the first bit line BL1 rise from low voltage Vss to high voltage V_{BLH} Here, Vss is, for example, 0 V, and V BLH is 2 V. Then, from time T3 to time T4, the voltage of the word line WL2 rises from low voltage Vss to high voltage V WLH. At this time, a fixed voltage of V PLL is being applied to the plate line PL2, causing currents to flow through the semiconductor base body 7 of the second semiconductor base body 202 for the memory cell C02 and the semiconductor base body 7 of the first semiconductor base body 201 for the memory cell C12. As a result, positive hole groups 9 are accumulated in the two semiconductor base bodies 7 by the impact ionization phenomenon. This situation is shown in FIG. 6E and FB “1” in FIG. 6F. Subsequently, as with the “1” writing operation described in FIGS. 3A to 3D, the voltage of the word line WL2 falls from high voltage V_{WLH} to low voltage Vss and the second bit line /BL0 and the first bit line BL1 fall from high voltage V_{BLH} to low voltage Vss, thereby finishing the data write operation of writing data “0” into the memory cell C02 and writing data “1” into the first memory cell C12.

Next, a data read operation (which is an example of a “data read operation” described in Claims) of the high-speed dynamic flash memory cell will be described using FIGS. 6G and 6H. As shown in FIG. 6G, data “1” writing is performed in the memory cells C01, C11, and C12, and positive hole groups 9 generated, for example, by the impact ionization phenomenon are accumulated in the semiconductor base body 7 of the first semiconductor base body 201 for the respective memory cells. Besides, data “0” writing is performed in the memory cells C00, C02, and C10, and positive hole groups 9 generated, for example, by the impact ionization phenomenon are accumulated in the semiconductor base body 7 of the second semiconductor base body 202 for the respective memory cells.

Description of the data read operation of the high-speed dynamic flash memory cell will be continued using FIGS. 6G and 6H. At time T1, the first bit lines BL0 and BL1 and the second bit lines /BL0 and /BL1 are pre-charged from low voltage Vss to high voltage V_{BLR} for reading. In this case, after being pre-charged to the high voltage V_{BLR} for reading, the first bit lines BL0 and BL1 and the second bit lines /BL0 and /BL1 may be allowed to float. Alternatively, for example, a load transistor of a p-channel MOS transistor may be connected to the first bit lines BL0 and BL1 and the second bit lines /BL0 and /BL1, with a dc voltage of the high voltage V BLR for reading applied thereto. In that case, load transistor current and memory cell current will counteract each other.

Description of the data read operation of the high-speed dynamic flash memory cell will be continued using FIGS. 6G and 6H. At time T2, the word line WL2 is, for example, selected, and rises from low voltage Vss to high voltage V_{WLR} for reading. Consequently, the memory cell current flows through the semiconductor base body 7 of the second semiconductor base body 202 for the memory cell C02 and the semiconductor base body 7 of the first semiconductor base body 201 for the memory cell C12, in which positive hole groups 9 have been accumulated. As a result, the second bit line /BL0 and the first bit line BL1 are discharged and fall from high voltage V_{BLR} for reading to low voltage Vss.

Description of the data read operation of the high-speed dynamic flash memory cell will be continued using FIGS. 6G and 6H. For example, at time T4, by activating the sense amplifier circuits SA0 and SA1, data is read to detect a potential difference between the first bit line and the second bit line. The data read by the sense amplifier circuits SA0 and SA1 is transferred to an output buffer (not shown) via the input-output lines by selecting column selection lines CSL0 and CSL1 in sequence. Finally, to reset the data read operation, the word line WL2 is returned from high voltage V WLR for reading to low voltage Vss at time 15 and the first bit line BL0 and the second bit line /BL1 are returned from high voltage V BLR for reading to low voltage Vss at time T6, thereby finishing the data read operation. Note that even after the read operation is finished, the voltage of all the plate lines PL are kept at V PLL to wait for a next operation cycle.

Note that in FIG. 1, desirably vertical length of the first gate conductor layer 5a connected with the plate line PL is made still larger than vertical length of the second gate conductor layer 5b connected with the word line WL such that C_{PL}>C_{WL}. However, by merely adding the plate line PL, a capacitive coupling ratio (C_{WL}/(C_{PL}+C_{WL}+C_{BL}+C_{SL})) of the word line WL to the semiconductor base body 7 is reduced. This reduces a potential fluctuation ΔV_{FB} in the semiconductor base body 7 of the floating body.

Besides, as the voltage V_{PLL} of the plate line PL, a fixed voltage of, for example, 2 V may be applied in operation modes other than those erased selectively in block erase operations.

In FIG. 1, operation of the dynamic flash memory described in the present embodiment can be performed even if a horizontal sectional shape of the Si pillar 2 is circular, elliptical, or rectangular. Besides, circular, elliptical, and rectangular dynamic flash memory cells may be allowed to coexist on a same chip.

In FIG. 1, a dynamic flash memory element has been described by taking as an example an SGT that includes the first gate insulating layer 4a surrounding an entire lateral surface of the Si pillar 2 erected in a vertical direction on the substrate 1, the second gate insulating layer 4b, and the first gate conductor layer 5a and second gate conductor layer 5b surrounding the entire first gate insulating layer 4a and second gate insulating layer 4b. As indicated in the description of the present embodiment, it is sufficient if the present dynamic flash memory element is structured to satisfy the condition that the positive hole groups 9 generated by the impact ionization phenomenon are held in the semiconductor base body 7. For that, it is sufficient that the semiconductor base body 7 has a floating body structure separated from the substrate 1. Consequently, the above-mentioned operation of the dynamic flash memory can be performed using, for example, GAA (Gate All Around; see, for example, E. Yoshida: “A Capacitorless 1T-DRAM Technology Using Gate-Induced Drain-Leakage (GIDL) Current for Low-Power and High-Speed Embedded Memory,” IEEE IEDM (2006)) technology, which is one of SGTs, or Nanosheet technology (see, for example, J. Y. Song, W. Y. Choi, J. H. Park, J. D. Lee, and B-G. Park: “Design Optimization of Gate-All-Around(GAA)MOSFETs,” IEEE Trans. Electron Devices, vol. 5, no. 3, pp. 186-191, May 2006), even if the semiconductor base body of the semiconductor base body is formed horizontally to the substrate 1. A device structure (see, for example, J. Wan, L. Rojer, A. Zaslaysky, and S. Critoloveanu: “A Compact Capacitor-Less High-Speed DRAM Using Field Effect-Controlled Charge Regeneration,” Electron Device Letters, Vol. 35, No. 2, pp. 179-181 (2012); T. Ohsawa, K. Fujita, T. Higashi, Y. Iwata, T. Kajiyama, Y. Asao, and K. Sunouchi: “Memory design using a one-transistor gain cell on SOI,” IEEE JSSC, vol. 37, No. 11, pp1510-1522 (2002); T. Shino, N. Kusunoki, T. Higashi, T. Ohsawa, K. Fujita, K. Hatsuda, N. Ikumi, F. Matsuoka, Y. Kajitani, R. Fukuda, Y. Watanabe, Y. Minami, A. Sakamoto, J. Nishimura, H. Nakajima, M. Morikado, K. Inoh, T. Hamamoto, A. Nitayama: “Floating Body RAM Technology and its Scalability to 32 nm Node and Beyond,” IEEE IEDM (2006); E. Yoshida: “A Capacitorless 1T-DRAM Technology Using Gate-Induced Drain-Leakage (GIDL) Current for Low-Power and High-Speed Embedded Memory,” IEEE IEDM (2006)) that uses SOI (Silicon On Insulator) may also be used. In this device structure, a bottom of a semiconductor base body is in contact with an insulating layer of an SOI substrate and surrounds other semiconductor base bodies while being surrounded by a gate insulating layer and an element separating insulating layer. In this structure, again the semiconductor base body has a floating body structure. In this way, it is sufficient if the dynamic flash memory element provided by the present embodiment satisfies the condition that the semiconductor base body has a floating body structure. Even with a structure in which a Fin transistor (see, for example, H. Jiang, N. Xu, B. Chen, L. Zengl, Y. He, G. Du, X. Liu and X. Zhang: “Experimental investigation of self-heating effect (SHE) in multiple-fin SOI FinFETs,” Semicond. Sci. Technol. 29 (2014) 115021 (7pp)) is formed on an SOI substrate, the present dynamic flash operation can be performed as long as the semiconductor base body has a floating body structure.

In “1” writing, electron-hole pairs may be generated (see, for example, E. Yoshida, and T. Tanaka: “A Capacitorless 1T-DRAM Technology Using Gate-Induced Drain-Leakage (GIDL) Current for Low-Power and High-Speed Embedded Memory,” IEEE Transactions on Electron Devices, Vol. 53, No. 4, pp. 692-69, Apr. 2006) using a gate induced drain leakage (GIDL) current and the semiconductor base body 7 may be filled with the generated positive hole groups 9.

Equations (1) to (10) in the present specification and drawings are used to quantitatively describe phenomena, and are not intended to limit the phenomena.

Besides, an example of conditions for the erase operation has been shown in FIG. 4B. In contrast, if a situation in which the positive hole groups 9 in the semiconductor base body 7 are removed from both or one of the N⁺ layer 3a and N⁺ layer 3b can be realized, the voltages applied to the source line SL, the plate line PL, the bit line BL, and the word line WL may be changed.

Besides, in a vertical direction in FIG. 1, in that part of the semiconductor base body 7 which is surrounded by the insulating layer 6, which is the first insulating layer, potential distributions of a first semiconductor base body 7a and second semiconductor base body 7b are formed by being joined together. Consequently, the first semiconductor base body 7a and second semiconductor base body 7b of the semiconductor base body 7 are joined together in the vertical direction via a region surrounded by the insulating layer 6, which is the first insulating layer.

Besides, in FIG. 1, the first gate conductor layer may be divided, in planar view or in a vertical direction, into two or more parts, which may be operated synchronously or asynchronously, each as a conductor electrode of a plate line, by a same drive voltage or different drive voltages. Similarly, the second gate conductor layer 5b may be divided, in planar view or in a vertical direction, into two or more parts, which may be operated synchronously or asynchronously, each as a conductor electrode of a word line, by a same drive voltage or different drive voltages. This also enables the dynamic flash memory operation. When the first gate conductor layer 5a is divided into two or more parts, at least one of the resulting first gate conductor layers serves the role of the first gate conductor layer 5a. Also, when the second gate conductor layer 5b is divided, at least one of the resulting second gate conductor layers serves the role of the second gate conductor layer 5b. In the vertical direction, one of the first gate conductor layer 5a and the second gate conductor layer 5b may be placed on opposite sides of the other gate conductor layer, i.e., the first gate conductor layer 5a or the second gate conductor layer 5b.

The conditions of the voltages applied to the bit lines BL, the source lines SL, the word lines WL, and the plate lines PL as well as the voltage of the floating body are exemplary in performing basic operations including erase operations, write operations, and read operations, and other voltage conditions that allow the basic operations of the present invention to be performed may be used.

Besides, in FIG. 1, the first gate conductor layer may be connected to the word line WL and the second gate conductor layer 5b may be connected to the plate line PL. This also enables the present dynamic flash memory operation described above.

The present embodiment has the following features.

(Feature 1)

In the dynamic flash memory cell according to the present embodiment, the N⁺ layers 3a and 3b, which are to become the source and the drain, the semiconductor base body 7, the first gate insulating layer 4a, the second gate insulating layer 4b, the first gate conductor layer and the second gate conductor layer 5b are formed into the shape of a pillar as a whole. Then, the N⁺ layer 3a to become the source is connected to the source line SL, the N⁺ layer 3b to become the drain is connected to the bit line BL, the first gate conductor layer 5a is connected to the plate line PL, and the second gate conductor layer 5b is connected to the word line WL. The gate capacitance of the first gate conductor layer 5a connected with the plate line PL is structured to be higher than the gate capacitance of the second gate conductor layer 5b connected with the word line WL. In the present dynamic flash memory cell, the first gate conductor layer and the second gate conductor layer are stacked in the vertical direction. Consequently, even if the gate capacitance of the first gate conductor layer 5a connected with the plate line PL is structured to be higher than the gate capacitance of the second gate conductor layer 5b connected with the word line WL, the area of the memory cell is not increased in planar view. This makes it possible to achieve higher performance and greater packaging density of the dynamic flash memory cell at the same time. During the data read, if the voltage to be applied to the first gate conductor layer 5a joined to the plate line PL is set higher than the threshold voltage at a time when the logical storage data is “1” and lower than the threshold voltage at a time when the logical storage data is “0,” the property that no current flows even if the voltage of the word line WL is increased is obtained. This leads to a further increase in an operating margin of the dynamic flash memory cell.

(Feature 2)

There are three major operation modes of the high-speed dynamic flash memory cell according to the first embodiment of the present invention: namely, erase operation, data write operation, and data read operation. In the data write operation, “1” data writing and “0” data writing are performed simultaneously. The bit line BL is made up of a set of two complementary two lines. Specifically, in the “1” data writing, the first bit line BLA is set to high voltage V_{BLH} to leave positive hole groups 9 in the semiconductor base body 7 of the first semiconductor base body 201 for a selected memory cell. In the “0” data writing, the second bit line /BLA is set to high voltage V BLH to leave positive hole groups 9 in the semiconductor base body 7 of the second semiconductor base body 202 for a selected memory cell. In this way, by constructing one memory cell from two semiconductor base bodies 201 and 202, and writing complementary data into the semiconductor base bodies 7, it is possible to achieve a faster read operation.

(Feature 3)

Taking a look at the role of the first gate conductor layer 5a connected with the plate line PL of the dynamic flash memory cell according to the first embodiment of the present invention, when the dynamic flash memory cell performs write and read operations, the voltage of the word line WL swings up and down. In so doing, the plate line PL serves the role of reducing the capacitive coupling ratio between the word line WL and the semiconductor base body 7. This makes it possible to greatly reduce the effect of voltage variations of the semiconductor base body 7 when the voltage of the word line WL swings up and down. This in turn makes it possible to increase a difference in the threshold voltage of an SGT transistor of the word line WL, the difference representing logic “0” or logic “1.” This leads to an increase in an operating margin of the dynamic flash memory cell.

### Second Embodiment

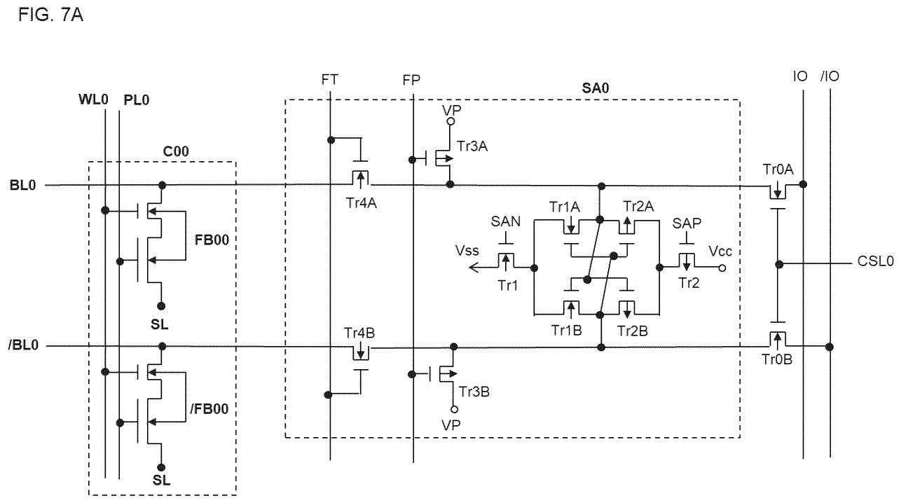

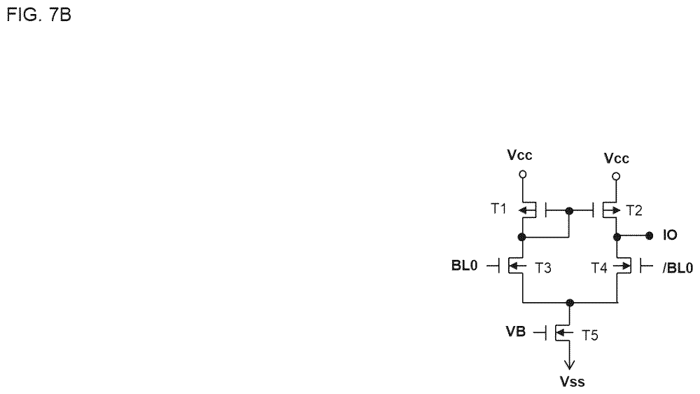

A read operation of a memory device having an SGT according to a second embodiment will be described with reference to FIGS. 7A and 7B.

FIG. 7A more specifically shows a circuit including the sense amplifier circuit SA0 shown in the circuit block diagrams of the high-speed dynamic flash memory cell of FIGS. 6E and 6G. Here, as the sense amplifier circuit SA0, for example, a dynamic sense amplifier circuit (which is an example of the “dynamic sense amplifier circuit” described in Claims) is shown. N-channel MOS transistors Tr1A and Tr1B and p-channel MOS transistors Tr2A and Tr2B make up a flip-flop circuit. An n-channel MOS transistor Tr1 that accepts input of an n-channel sense amplifier activation signal SAN in its gate and a p-channel MOS transistor Tr2 that accepts input of a p-channel sense amplifier activation signal SAP in its gate activate the flip-flop circuit. As a result, in a data write operation, write data loaded via the input-output lines IO and /IO is latched by the flip-flop circuit via n-channel MOS transistors Tr0A and Tr0B whose gates receive input from the column selection line CSL0. In a data read operation, write data of the memory cell C00 is selected by the word line WL0, read to the first bit line BL0 and the second bit line/BL0, read to the flip-flop circuit via n-channel MOS transistors Tr4A and Tr4B whose gates accept input of a transfer signal FT, and latched by the flip-flop circuit. Just before the data write operation and the data read operation, the flip-flop circuit is reset and the first bit line BL0 and the second bit line/BL0 are pre-charged by n-channel MOS transistors Tr3A and Tr3B whose gates accept input of a pre-charge signal FP. Note that in the data write operation and the data read operation, the voltage of the plate line PL0 is set to a low voltage V PLL. In this way, write data and read data are latched by the dynamic sense amplifier circuit, enabling a high-speed data write operation and data read operation.

FIG. 7B shows a differential amplifier (which is an example of a “differential amplifier” described in Claims). The differential amplifier is used for data read operations and allows faster data reading. When write data of the memory cell C00 is read to the first bit line BL0 and the second bit line /BL0, a potential difference is produced between the bit lines. The potential difference is inputted to the gates of re-channel MOS transistors T3 and T4 and data is outputted statically to the output line IO based on currents flowing through the transistors T3 and T4. Here, p-channel MOS transistors T1 and T2 make up a current mirror circuit and a bias voltage VB is inputted to a gate of an n-channel MOS transistor 15. A supply voltage Vcc and a ground voltage Vss are also inputted.

As a bit line pair for reading is inputted to the differential amplifier in this way, high-speed reading can be achieved. However, because the bit line pair is inputted to a gate of the differential amplifier, i.e., input and output are separated, and as a sense amplifier circuit for data write operations, for example, a dynamic sense amplifier circuit needs to be connected in parallel with the differential amplifier. Therefore, regarding such differential amplifiers for high-speed reading, although a set of differential amplifiers may be connected in parallel per bit line, a set of differential amplifiers may be provided for multiple pairs of bit lines such as four pairs or eight pairs.

(Feature)

The dynamic sense amplifier circuit shown in FIG. 7A allows the high-speed dynamic flash memory cell to perform data write operations and data read operations at high speed.

### Third Embodiment

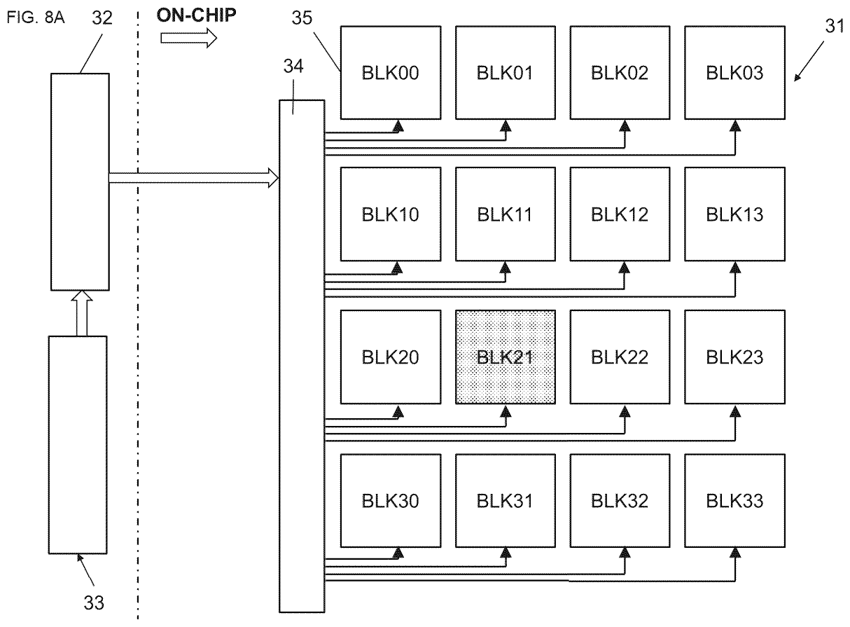

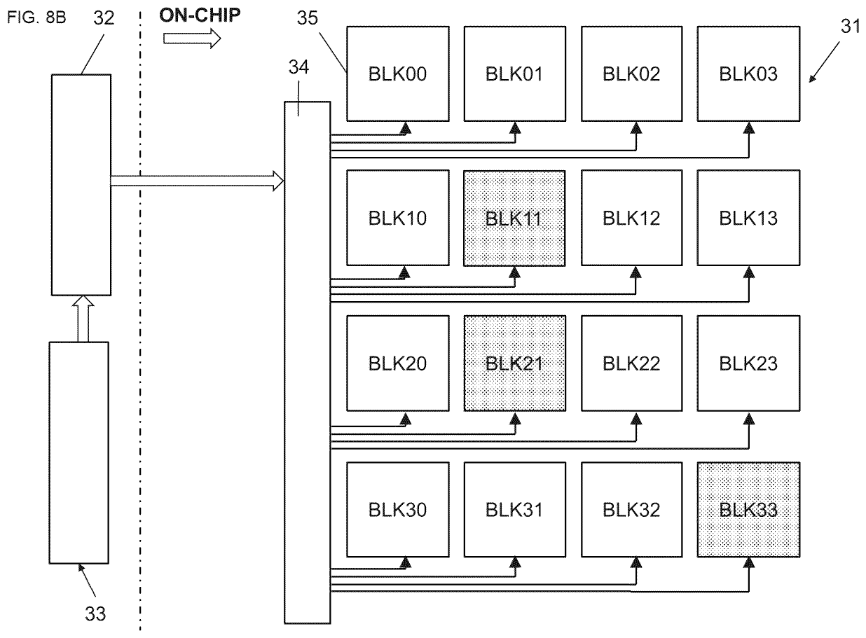

FIGS. 8A and 8B show circuit block diagrams of a chip of a high-speed dynamic flash memory cell according to a third embodiment.

In FIG. 8A, correspondence between data stored at logical-physical block addresses and physical block addresses of the high-speed dynamic flash memory is always managed by a controller circuit 33 and a logical-physical block address conversion lookup table circuit (abbreviated to logical-physical conversion table) 32. This is because in the high-speed dynamic flash memory, as with the flash memory, data in blocks are rewritten using already erased blocks, making it necessary to constantly manage correspondence between logical block addresses and physical block addresses. The controller circuit 33 and the logical-physical conversion table 32 may be provided in the chip of the high-speed dynamic flash memory, but may alternatively be provided outside the chip as shown in FIG. 8A. Commands from the logical-physical conversion table 32 are inputted to a block address decoder circuit 34 and blocks to be erased, written, or read are selected from blocks BLK00 to BLK33.

In FIG. 8A, it is assumed that a command to read storage data from block BLK21 out of 4×4=16 blocks, i.e., blocks BLK00 to BLK33 of the high-speed dynamic flash memory, is issued by the controller circuit 33. In FIG. 8B, it is assumed that a command to read storage data from three blocks BLK11, BLK21, and BLK33 is issued by the controller circuit 33. In this way, regarding block selection, not only one, but also multiple blocks may be selected and read simultaneously. Besides, for example, an erase operation of BLK11, a “1” writing operation of block BLK21, and a read operation of block BLK33 may be performed simultaneously. In this way, not only a same operation, but also different operations such as an erase operation, a write operation, and a read operation may be selected and performed simultaneously with respect to multiple blocks, making it possible to efficiently use a large-capacity high-speed dynamic flash memory.

Note that for block rewrite and block erase operations, a cache memory (not shown) may sometimes be necessary to temporarily store storage data of blocks to be rewritten. The cache memory may be provided within or outside the chip of the high-speed dynamic flash memory according to the present embodiment.

The logical-physical conversion table 32 or the cache memory may be made up of the high-speed dynamic flash memory cell and blocks BLK00 to BLK33 may be made up of a dynamic flash memory cell.

Besides, to maintain storage data in blocks, a refresh operation may be performed on a block by block basis. In this case, because the block at the given physical address is refreshed, there is no need to perform a block rewrite operation or block erase operation.

(Feature)

The high-speed dynamic flash memory cell according to the third embodiment can be controlled separately on a block by block basis, making it possible to select two or more blocks and perform different modes of operation such as an erase operation, a write operation, and a read operation simultaneously. This in turn makes it possible to achieve a speedup and efficient use of the high-speed dynamic flash memory cell.

### Fourth Embodiment

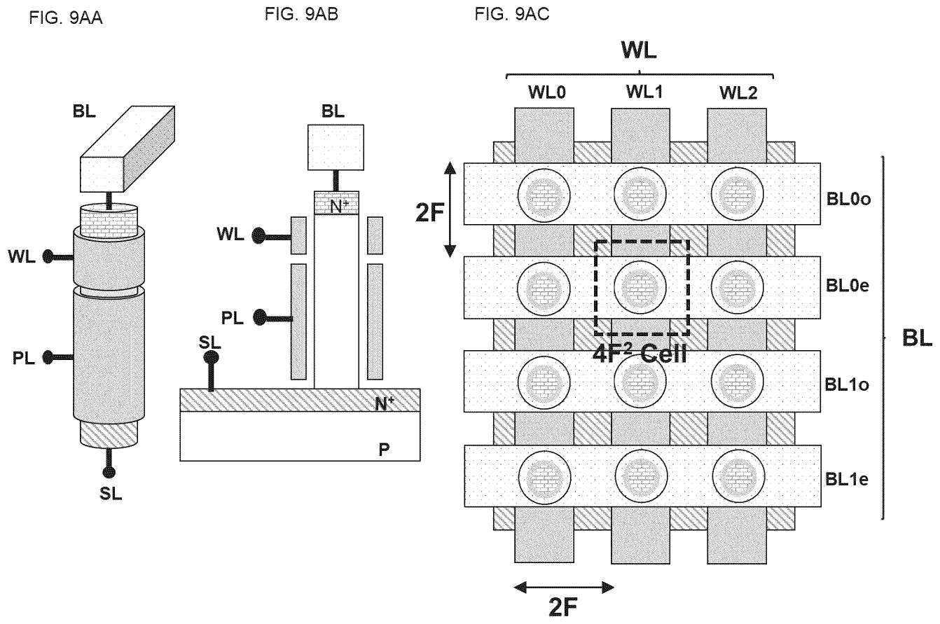

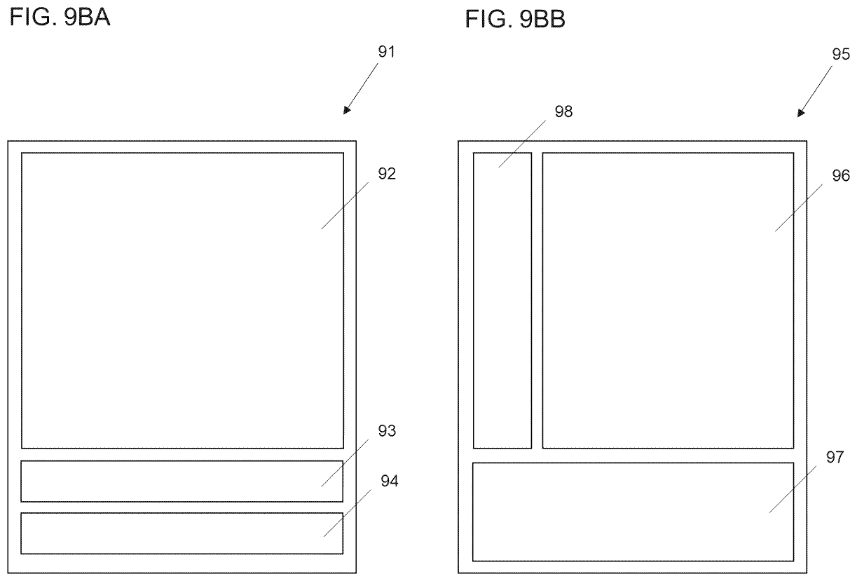

FIGS. 9AA to 9BB show diagrams for explaining an application example of a high-speed dynamic flash memory cell according to a fourth embodiment.

FIGS. 9AA and 9AB show a bird's-eye view and sectional view of a 1-bit dynamic flash memory cell which is a second memory cell (which is an example of a “second memory cell” described in Claims) and which is made up of one semiconductor base body. In FIGS. 9AA and 9AB, the dynamic flash memory cell is connected with the bit line BL, the source line SL, the plate line PL, and the word line WL. FIG. RAC shows a plan view of a second block (which is an example of a “second block” described in Claims) in which multiple, namely, 3×4, dynamic flash memory cells are arrayed in a matrix. The dynamic flash memory cells can be arrayed by setting the pitch of the bit lines BL to 2F, the pitch of the word lines WL to 2F, and the 1-bit memory cell size to 4F×2F=4F2, where F is feature size, which is one of design rules or ground rules. In a miniaturized dynamic flash memory cell, for example, F=15 nm. As a result, when adjacent bit lines BL read “1” written memory cells and “0” erased memory cells, capacitive coupling among the bit lines is strong, which requires ingenuity in a reading method. In FIG. 6A (first embodiment), in the high-speed dynamic flash memory cell 200, which is the first memory cell, the first semiconductor base body 201 and the second semiconductor base body 202 make up a 1-bit memory cell and complementary data is stored in the first semiconductor base body 201 and the second semiconductor base body 202. Static reading, which is used, is resistant to noise and features high-speed reading. On the other hand, for the dynamic flash memory cell that enables greater packaging density and allows one semiconductor base body to make up 1-bit memory cell, for example, a bit line shielding technique may be used. The bit line shielding technique, which is used in a data read operation and/or a data write operation, involves grounding every other bit line for use as shield lines and reading and writing data through the other bit lines.

FIGS. 9BA and 9BB show a memory chip 91 (which is an example of a “memory chip” described in Claims) and a logic chip 95 (which is an example of a “logic chip” described in Claims), on which a second block made up of a dynamic flash memory cell which is a second memory cell and a first block made up of a high-speed dynamic flash memory cell which is a first memory cell are mounted in a mixture. In FIG. 9BA, most of the area occupied by the memory chip 91 is a second block 92 made up of a dynamic flash memory cell, a first block 93 made up of a high-speed dynamic flash memory cell which is a first memory cell is mounted in a mixture with other elements in part of the area, and the rest of the area is allocated to a peripheral circuit 94. The first block that allows high-speed reading is applied as a cache memory, or used as data memory for booting. Alternatively, the first block may be used to store a logical-physical conversion table.

The logic chip 95 shown in FIG. 9BB includes a second block 96 made up of a dynamic flash memory cell, CPU or GPU 97, and the first block 98 made up of a high-speed dynamic flash memory cell which is a first memory cell. A SPAM area used as a cache memory of a conventional CPU or GPU 97 can be replaced to some extent by the first block 98 made up of a high-speed dynamic flash memory cell which is a first memory cell.

(Feature)

An application area of the high-speed dynamic flash memory cell according to the fourth embodiment spread wide. This is because the dynamic flash memory cell according to the present embodiment is higher in speed than conventional DRAMs, and in particular, is quick in writing and reading large numbers of bits simultaneously. The memory cell size is only 8F², which is smaller than conventional SRAM memory cells even by an order of magnitude. This makes it possible to develop memory chips or logic chips carrying large-capacity high-speed dynamic flash memory cells in a mixture with other elements.

### OTHER EMBODIMENTS

Note that whereas a Si pillar is formed in the present invention, a semiconductor pillar made of a semiconductor material other than Si may be used. This similarly applies to other embodiments of the present invention.

According to the third embodiment, the logical-physical conversion table in FIGS. 8A and 8B is provided outside the chip of the semiconductor memory device, but may be provided on-chip within the semiconductor memory device. This similarly applies to other embodiments of the present invention.

By providing a timer circuit for each of the blocks BLK00 to BLK33 according to the third embodiment in FIGS. 8A and 8B, the block may be refreshed on instructions from the timer circuit. This similarly applies to other embodiments of the present invention.

In a vertical NAND-type flash memory circuit, using a semiconductor pillar as a channel, multiple stacks of memory cells made up of a tunnel oxide layer, a charge storage layer, an interlayer insulation layer, and a control conductor layer surrounding the semiconductor pillar are formed in the vertical direction. There are a source line impurity region corresponding to a source and a bit line impurity region corresponding to a drain on opposite ends of the semiconductor pillar of the memory cells. If, for one memory cell, one of memory cells on opposite sides of the memory cell is a source, the memory cell on the other side serves as a drain. In this way, the vertical NAND-type flash memory circuit is a type of SGT circuits. Thus, the present invention is applicable to a mixed circuit with a NAND-type flash memory circuit.

In FIG. 1, in a structure in which polarity of conductivity type of each of the N⁺ layers 3a and 3b and p-layer Si pillar 2 is reversed, the dynamic flash memory operation is performed. In this case, in the Si pillar 2, which is n-type, majority carriers become electrons. Thus, electron groups generated by impact ionization are accumulated in the semiconductor base body 7, and a “1” state is established. Alternatively, a junctionless structure, in which the N⁺ layers 3a and 3b become P⁺ layers or the p-layer Si pillar 2 becomes an n-layer Si pillar, may be used.

The present invention can be embodied or modified in various forms without departing from the spirit and scope of the present invention in a broad sense. Also, the embodiments described above are meant to be illustrative, and not to limit the scope of the present invention. The embodiments and variations described above can be combined as desired. Furthermore, even if some components of the embodiments described above are removed as required, the resulting inventions fall within the scope of the technical idea of the present invention.

### INDUSTRIAL APPLICABILITY

The semiconductor memory device that uses an SGT according to the present invention provides a high-speed dynamic flash memory, which is a memory device that uses a high-density, high-performance SGT.

What is claimed is:

1. A semiconductor element memory device comprising:
a first block in which a plurality of first memory cells is arrayed in a matrix; and
first and second semiconductor elements included in the first memory cells, each of the first and second semiconductor elements in turn including:
a semiconductor base body erected on a substrate in a vertical direction of the substrate or extended on the substrate in a horizontal direction,
a first impurity region and a second impurity region provided on opposite ends of the semiconductor base body;
a gate insulating layer placed in contact with a lateral surface of the semiconductor base body between the first impurity region and the second impurity region;
a first gate conductor layer covering part or all of the gate insulating layer; and
a second gate conductor layer located adjacent to the first gate conductor layer and placed in contact with a lateral surface of the gate insulating layer,
wherein positive hole groups generated by an impact ionization phenomenon or by a gate-induced drain leakage current are held in the semiconductor base body by controlling voltages applied to the first gate conductor layer, the second gate conductor layer, the first impurity region, and the second impurity region,
of the first semiconductor elements of the first memory cells, the first impurity region is connected with a source line, the second impurity region is connected with a first bit line, and one of the first gate conductor layer and the second gate conductor layer is connected with a word line and another is connected with a drive control line, and
of the second semiconductor elements of the first memory cells, the first impurity region is connected with the source line, the second impurity region is connected with a second bit line, and one of the first gate conductor layer and the second gate conductor layer is connected with the word line, and another is connected with the drive control line.

2. The semiconductor element memory device according to claim 1, wherein during a data write operation, one of a voltage of the semiconductor base body of the first semiconductor elements and a voltage of the semiconductor base body of the second semiconductor elements serves as a first data retention voltage, and another serves as a second data retention voltage.

3. The semiconductor element memory device according to claim 1, wherein each of the first memory cells has a capacity of 1 bit.

4. The semiconductor element memory device according to claim 1, wherein the first bit line and the second bit line are connected to a dynamic sense amplifier circuit to read data from the first memory cells and write data to the first memory cells via the dynamic sense amplifier circuit.

5. The semiconductor element memory device according to claim 1, wherein the first bit line and the second bit line are connected to a differential amplifier circuit to read data from the first memory cells via the differential amplifier circuit.

6. The semiconductor element memory device according to claim 1, wherein the first block is mounted in a mixture with other elements on a logic chip.

7. The semiconductor element memory device according to claim 1, further comprising a second block in which a plurality of second memory cells is arrayed in a matrix, wherein:
the second memory cells include the first semiconductor elements or second semiconductor elements as semiconductor elements;
of the semiconductor elements of the second memory cells, the first impurity region is connected with a source line, the second impurity region is connected with a bit line, and one of the first gate conductor layer and the second gate conductor layer is connected with a word line and another is connected with a drive control line; and
the second block is mounted in a mixture with the first block on a memory chip.

8. The semiconductor element memory device according to claim 1, wherein one or both of the first gate conductor layer and the second gate conductor layer are divided into two or more separate gate conductor layers in planar view or in a vertical direction and the separate gate conductor layers are operated synchronously or asynchronously.

9. The semiconductor element memory device according to claim 8, wherein in the vertical direction, either the separate gate conductor layers of the first gate conductor layer are placed on opposite sides of the second gate conductor layer, or the separate gate conductor layers of the second gate conductor layer are placed on opposite sides of the first gate conductor layer.
